(19) United States
(12) Patent Application Publication
(10) Pub. No.: US 2023/0275107 A1
(43) Pub. Date: Aug. 31, 2023

(54) Light Sensing Panel and Light Sensing Display Panel

(71) Applicant: HANNSTOUCH SOLUTION INCORPORATED, Tainan City (TW)

(72) Inventor: Che-Yu CHUANG, Tainan City (TW)

(21) Appl. No.: 17/680,331

(22) Filed: Feb. 25, 2022

(51) Int. Cl. H01L 27/146; G01J 1/16

(52) U.S. Cl. CPC H01L 27/14616; G01J 1/1626; H01L 27/14636; G02F 1/13312

(57) ABSTRACT

A light sensing panel includes a substrate, at least one readout line, at least one scan line, and at least one pixel unit. The substrate has an array region and a peripheral region. The readout line and the scan line extend at least over the array region of the substrate. The pixel unit is over the array region of the substrate and electrically connected to the readout line and the scan line. The pixel unit at least includes a sensing switch device, a light sensing device, and a reference light sensing device. A first terminal of the sensing switch device is connected to the readout line. The light sensing device is connected between a second terminal of the sensing switch device and a voltage source. The reference light sensing device is connected between the second terminal of the sensing switch device and a grounded source.

### BACKGROUND

### Field of Invention

The present invention relates to a light sensing panel and a light sensing display panel.

### Description of Related Art

Photoelectric sensors can convert light into current or voltage signals. The photoelectric sensors can be manufactured in the form of thin film transistors and arranged in an array, which is then used in the fields of optical touch, fingerprint recognition, X-ray detection, etc. The photoelectric sensor may include a semiconductor thin film having a suitable band gap corresponding to the wavelength of light to be absorbed.

### SUMMARY

In some embodiments of the present invention, the light sensing device is used to receive light to generate current, and a reference light sensing device that is not exposed to the light is designed to be connected in series with the light sensing device, thereby directly deducting a dark current from the current of the light sensing device. This design can improve the contrast of the read current, thereby improving the contrast of the image.

According to some embodiments of the present invention, a light sensing panel includes a substrate, at least one readout line, at least one scan line, and at least one pixel unit. The substrate has an array region and a peripheral region. The readout line and the scan line extend at least over the array region of the substrate. The pixel unit is over the array region of the substrate and electrically connected to the readout line and the scan line. The pixel unit at least includes a sensing switch device, a light sensing device, and a reference light sensing device. A first terminal of the sensing switch device is connected to the readout line. The light sensing device is connected between a second terminal of the sensing switch device and a voltage source. The reference light sensing device is connected between the second terminal of the sensing switch device and a grounded source.

In some embodiments, a control terminal of the light sensing device and a control terminal of the reference light sensing device are electrically connected to the voltage source.

In some embodiments, the light sensing device, the reference light sensing device, and the sensing switch device are thin-film transistors.

In some embodiments, a length of a channel region of the light sensing device is the same as a length of a channel region of the reference light sensing device.

In some embodiments, a first difference is between a length of a channel region of the light sensing device and a length of a channel region of the reference light sensing device, a second difference is between the length of the channel region of the light sensing device and a length of a channel region of the sensing switch device, and the second difference is greater than the first difference.

In some embodiments, the light sensing device comprises a gate electrode, two source/drain electrodes, and a channel region between the source/drain electrodes, the channel region comprises a first portion and a second portion, the first portion of the channel region overlaps the gate electrode, and the second portion of the channel region does not overlap the gate electrode.

In some embodiments, the reference light sensing device comprises a reference gate electrode, two reference source/drain electrodes, and a reference channel region between the reference source/drain electrodes, the reference channel region comprises a first reference portion and a second reference portion, the first reference portion of the reference channel region overlaps the reference gate electrode, and the second reference portion of the reference channel region does not overlap the reference gate electrode.

In some embodiments, a length of the first reference portion of the reference channel region of the reference light sensing device is the same as a length of the first portion of the channel region of the light sensing device.

In some embodiments, the first portion of the channel region is adjacent to one of the source/drain electrodes, and the second portion of the channel region is adjacent to another one of the source/drain electrodes.

According to some embodiments of the present invention, a light sensing display panel includes the aforementioned light sensing panel and at least one data line. The data line is disposed over the substrate. The pixel unit further includes a display switch device and a pixel electrode, a control terminal of the display switch device is connected to the scan line, and two terminals of the display switch device are respectively electrically connected to the data line and the pixel electrode.

### BRIEF DESCRIPTION OF THE DRAWINGS

Aspects of the present invention are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic top view of a light sensing panel according to some embodiments of the present invention.

FIG. 1B is a circuit diagram of a pixel portion of the light sensing panel of FIG. 1A.

FIG. 2A is a schematic top view of a portion of a pixel unit of a light sensing panel according to some embodiments of the present invention.

FIG. 2B is a schematic cross-sectional view of a portion of a pixel unit according to some embodiments of the present invention.

FIG. 3 is a schematic top view of a light sensing display panel according to some embodiments of the present invention.

FIG. 4 is a schematic cross-sectional view of portions of a light sensing display panel according to some embodiments of the present invention.

### DETAILED DESCRIPTION

The following invention provides many different embodiments, or examples, for implementing different features of the provided subject matter. Specific examples of components and arrangements are described below to simplify the present invention. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

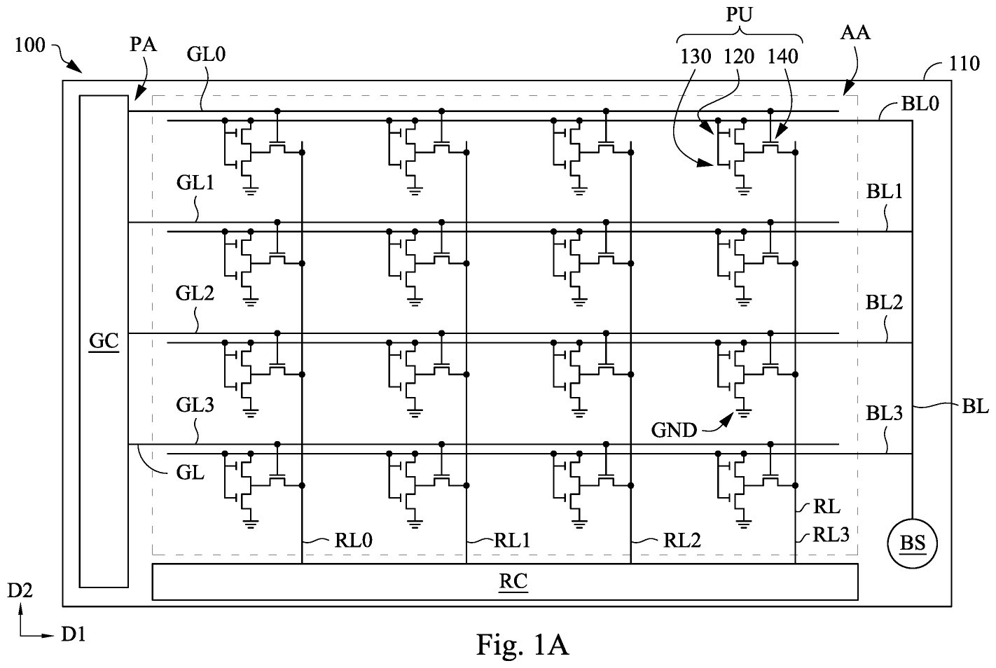

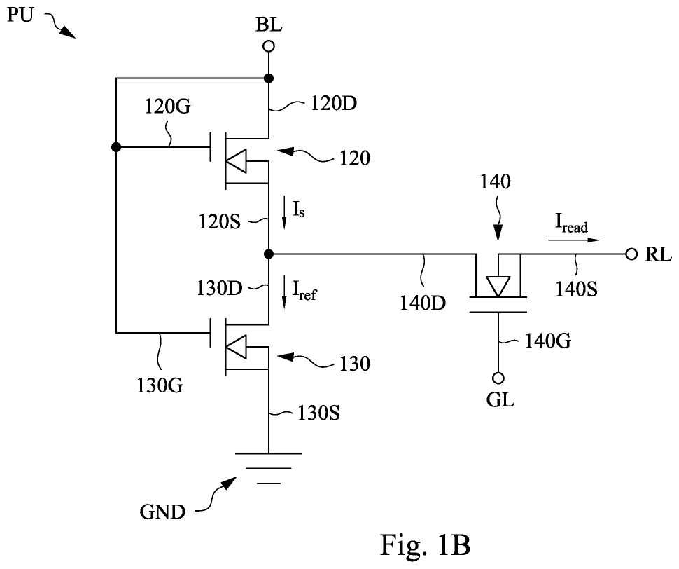

FIG. 1A is a schematic top view of a light sensing panel 100 according to some embodiments of the present invention. The light sensing panel 100 includes a substrate 110, plural pixel units PU, plural scan lines GL (e.g., scan lines GL0-GL3), readout lines RL (e.g., readout lines RL0-RL3), a bias line BL, scan driving circuit GC, and readout circuit RC. The substrate 110 may include an array region AA and a peripheral region PA at at least one side of the array region AA, the pixel unit PU is disposed over the array region AA, the scan lines GL (e.g., scan lines GL0-GL3), the readout lines RL (e.g., readout lines RL0-RL3), and the bias line BL extend over the array region AA and to the peripheral region PA. The scan driving circuit GC and the readout circuit RC may be disposed directly over the peripheral region PA of the substrate 110 or connected to the peripheral region PA through flexible circuit board.

In the present embodiments, each of the pixel units PU is connected to a scan line GL (e.g., one of scan lines GL0-GL3) and a readout line RL (e.g., one of readout lines RL0-RL3). The scan lines GL (e.g., scan lines GL0-GL3) can be connected to the scan driving circuit GC, thereby time-sequentially providing scan signals to the pixel units PU. The readout lines RL can be connected to the readout circuit RC, thereby sending currents to the readout circuit RC. The bias line BL is connected to a voltage source BS, in which the voltage source BS provides a suitable and stable voltage potential. In some embodiments, the scan lines GL, the readout lines RL, and the bias line BL are electrically disconnected from each other. In some embodiments, the scan lines GL extend along a first direction D1, the readout lines RL extend along a second direction D2, and the first direction D1 intersects the second direction D2. For example, the first direction D1 is perpendicular to the second direction D2. In the present embodiments, the bias line BL has extension lines BL0-BL3 extending along the first direction D1 and parallel with the scan lines GL. Of course, it should not limit the scope of the present disclosure. In some other embodiments, the extension lines BL0-BL3 of the bias line BL may extend along the second direction D2 and parallel with the readout lines RL.

FIG. 1B is a circuit diagram of a portion of the light sensing panel 100 of FIG. 1A. Reference is made to FIGS. 1A and 1B. Each of the pixel units PU may include a light sensing device 120, a reference light sensing device 130, and a sensing switch device 140.

The light sensing device 120 may include a control terminal 120G, a first terminal 120D, and a second terminal 120S, in which a resistance between the first terminal 120D and the second terminal 120S may be controlled by light and a signal applied on the control terminal 120G. The reference light sensing device 130 may include a control terminal 130G, a first terminal 130D, and a second terminal 130S, in which a resistance between the first terminal 130D and the second terminal 130S may be controlled by light and a signal applied on the control terminal 130G. The sensing switch device 140 may include a control terminal 140G, a first terminal 140D, and a second terminal 140S, in which a resistance between the first terminal 140D and the second terminal 140S may be controlled by a signal applied on the control terminal 140G.

In some embodiments, the first terminal 120D and the control terminal 120G of the light sensing device 120 can be connected to the voltage source BS through the bias line BL, and the second terminal 120S of the light sensing device 120 can be connected to the readout line RL (e.g., the readout lines RL0-RL3) through the sensing switching device 140. In some embodiments, the first terminal 130D of the reference light sensing device 130 is connected to the second terminal 120S of the light sensing device 120. That is, the first terminal 130D of the reference light sensing device 130 can be connected to the readout line RL (e.g., the readout lines RL0-RL3) through the sensing switching device 140. The second terminal 130S of the reference light sensing device 130 is grounded (e.g., connected to the grounded source GND). The control terminal 130G of the reference light sensing device 130 can also be connected to the voltage source BS by the bias line BL. The control terminal 140G of the sensing switch device 140 is connected to the scan line GL (e.g., the scan lines GL0-GL3), the first terminal 140D of the sensing switch device 140 is connected to the second terminal 120S of the light sensing device 120 and the first terminal 130D of the reference light sensing device 130, and the second terminal 140S is connected to the readout line RL (e.g., the readout lines RL0-RL3).

Through the configuration, as the scan driving circuit GC sends signals to the respective scan lines GL (e.g., the scan lines GL0-GL3), the sensing switch devices 140 of respective rows of the pixels PU can be sequentially turned on. Thus, currents generated by the light sensing devices 120 may flow through the sensing switch devices 140, and then be sent to the readout circuit RC by the respective readout lines RL (e.g., the readout lines RL0-RL3).

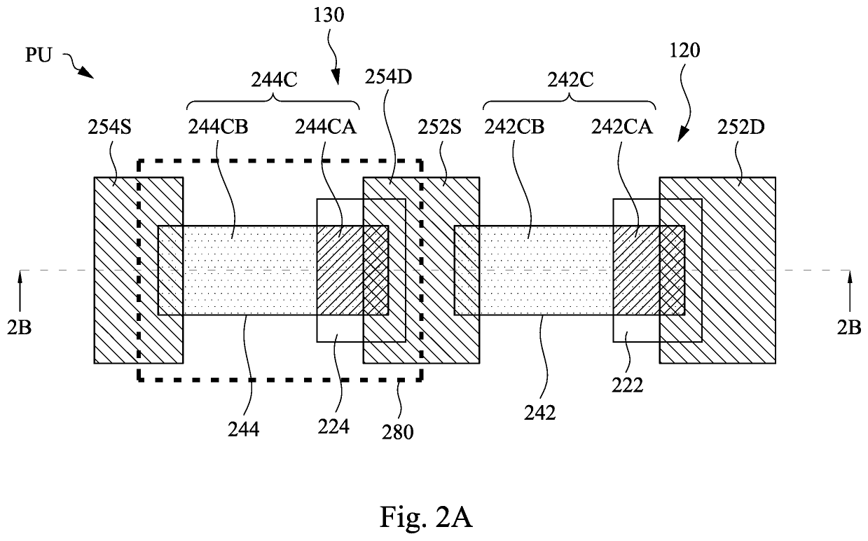

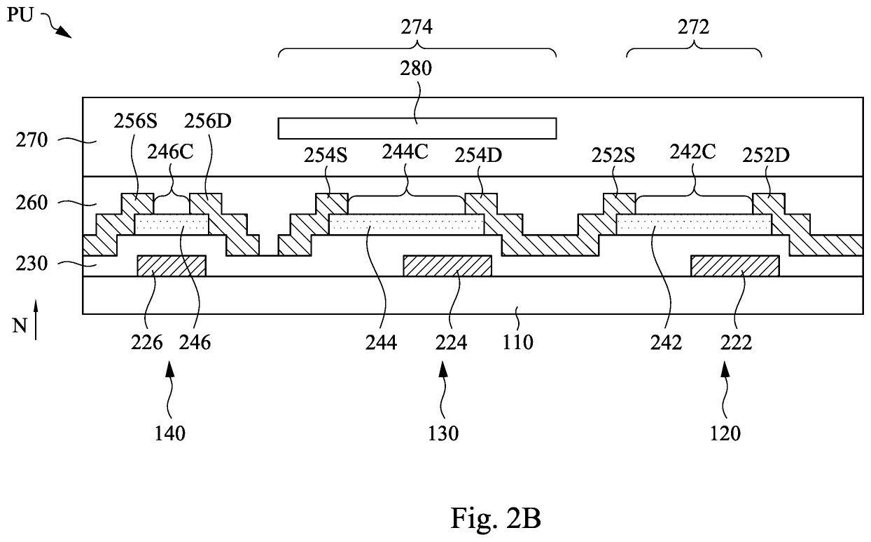

In some embodiments of the present disclosure, the reference light sensing device 130 have a similar structure and type to the light sensing device 120, except that the reference light sensing device 130 is designed not to be exposed to light. For example, with reference to FIGS. 2A and 2B, a light shielding layer 280 covers the reference light sensing device 130, but does not cover the light sensing device 120. Referring back to FIG. 1B, in some embodiments of the present disclosure, the light sensing device 120 is connected between the bias line BL (or the voltage source BS) and the first terminal 140D of the sensing switch device 140, the reference light sensing device 130 is connected between the first terminal 140D of the sensing switch device 140 and the grounded source GND. Through the configuration, a magnitude of the current flowing through the reference light sensing device 130 (can be referred to as a reference current I_{ref}) can be deemed as equivalent to a magnitude of a dark current in the light sensing device 120. Through the circuit design, as the current Iₛ flows through the light sensing device 120, a portion of the current Iₛ would be sent to the reference light sensing device 130 and thus become the reference current I_{ref}, and another portion of the current Iₛ would be output as the read current I_{read}. Through the configuration, the dark current (a magnitude of which is equal to that of the reference current I_{ref}) can be deducted from the current Iₛ in the light sensing device 120, thereby obtaining the read current I_{read}. Light sensing panel 100 obtains an image through the magnitudes of the read currents I_{read} of the respectively pixel units PU, in which the contrast of the image comes from the contrast of the read currents I_{read}. Therefore, in some embodiments of the present disclosure, through the design of the reference light sensing device 130, the contrast of the read currents I_{read} can be increased, thereby increasing the contrast of the image.

For example, when the panel is exposed to light, the current Iₛ in the light sensing device 120 is 10 nA, the reference current I_{ref} flowing through the reference light sensing device 130 is 0.9 nA, and at this point, the read current I_{read} is 9.1 nA; when the panel is not exposed to light, the current Iₛ in the light sensing device 120 is 1 nA, the reference current I_{ref} flowing through the reference light sensing device 130 is 0.9 nA, and at this point, the read current I_{read} is 0.1 nA. According, it is can be found that the contrast ratio of the read current I_{read} increases from 10 (i.e., 10 nA/1 nA) to 91 (i.e., 9.1 nA/0.1 nA).

FIG. 2A is a schematic top view of a portion of a pixel unit PU of a light sensing panel according to some embodiments of the present invention. FIG. 2B is a schematic cross-sectional view of a portion of the pixel unit PU according to some embodiments of the present invention, in which FIG. 2B includes a schematic cross-sectional view taken along line 2B-2B of FIG. 2A. Reference made to both FIGS. 2A and 2B. In some embodiments, the light sensing device 120, the reference light sensing device 130, and the sensing switch device 140 are disposed over the substrate 110. An exemplary method for fabricating the light sensing device 120, the reference light sensing device 130, and the sensing switch device 140 is illustrated below. It should be understood that the illustrated method is not intended to limit the scope of the present disclosure, and other fabrication methods may also be applicable.

In some embodiments, the substrate 110 can be a rigid substrate having a suitable hardness or a flexible substrate. The substrate can be made of glass, quartz, organic material (e.g., polymeric material), other suitable material, or the combination thereof.

In some embodiments, a metal layer can be deposited over the substrate 110, and then be patterned by an etching process to form gate electrodes 222, 224, 226. As a result, the gate electrodes 222, 224, 226 can have the same material and similar thicknesses. For example, the gate electrodes 222, 224, 226 can be formed by a suitable conductive material, such as molybdenum, titanium, chromium, tantalum, tungsten, aluminum, copper, other metals, their alloys, or combinations thereof.

An insulating layer 230 may be deposited on the gate electrodes 222, 224, 226. The insulating layer 230 may be formed by depositing a suitable insulating material, such as silicon nitride, silicon oxide, silicon oxynitride, or a combination thereof.

Subsequently, a semiconductor thin film may be deposited over the insulating layer 230, and then the semiconductor thin film may be patterned through an etching process to form the semiconductor layers 242, 244, and 246. As a result, the semiconductor layers 242, 244, 246 may have the same material and similar thicknesses. For example, the semiconductor layers 242, 244, and 246 can be selected from semiconductor materials with appropriate energy gaps, which can absorb light and change their resistance accordingly. For example, the semiconductor layers 242, 244, 246 may be formed of a suitable semiconductor material, such as amorphous silicon, N-type lightly doped (n+) amorphous silicon, other suitable materials, or combinations thereof.

Then, a metal layer is deposited, and the metal layer is then patterned by an etching process to form source/drain electrodes 252S, 252D, 254S, 254D, 256S, and 256D, which are respectively connected to opposite two ends of the respective semiconductor layers 242, 244, and 246. As a result, the source/drain electrodes 252S, 252D, 254S, 254D, 256S, and 256D may have the same material and similar thicknesses. The source/drain electrodes 252S, 252D, 254S, 254D, 256S, and 256D can be formed by a suitable conductive material, such as molybdenum, titanium, chromium, tantalum, tungsten, aluminum, copper, other metals, their alloys, or combinations thereof.

Through the configuration, the light sensing device 120, the reference light sensing device 130, and the sensing switch device 140 are formed. The light sensing device 120 includes the gate electrode 222, the semiconductor layer 242, and the source/drain electrodes 252S, 252D, in which the gate electrode 222 and the source/drain electrodes 252S, 252D respectively correspond to the control terminal 120G, the second terminal 120S, and the first terminal 120D in FIG. 1B. The reference light sensing device 130 includes the gate electrode 224, the semiconductor layer 244, and the source/drain electrodes 2524, 254D, in which the gate electrode 224 and the source/drain electrodes 2524, 254D respectively correspond to the control terminal 130G, the second terminal 130S, and the first terminal 130D in FIG. 1B. The sensing switch device 140 includes the gate electrode 226, the semiconductor layer 246, and the source/drain electrodes 2564, 256D, in which the gate electrode 226 and the source/drain electrodes 2564, 256D respectively correspond to the control terminal 140G, the second terminal 140S, and the first terminal 140D in FIG. 1B. In plural embodiments of the present disclosure, the light sensing device 120, the reference light sensing device 130, and the sensing switch device 140 may adopt N-type channels or P-type channels, and not limited by those shown in figures.

In some embodiments of the present disclosure, for the light sensing device 120, the semiconductor layer 242 has a channel region 242C between the source/drain electrodes 252S and 252D. The gate electrode 222 is offset disposed, and thus the channel region 242C is divided into a switch area 242A and a sensing are 242CB, in which the switch area 242A overlaps the gate electrode 222 along a direction N, and the light sensing area 242CB does not overlap the gate electrode 222 along the direction N. The direction N may be normal to a top surface of the substrate 110. Through the configuration, an electron channel of an entirety of the channel region 242C of the semiconductor layer 242 (i.e., the switch area 242CA and the light sensing area 242CB) is controlled by the light, and thus can sense light, in which the electron channel of the switch area 242CA of the semiconductor layer 242 can be further controlled by the gate electrode 222. In the present embodiments, with the design of the offset gate electrode, the switch area 242CA is adjacent to one of the source/drain electrodes 252S and 252D, and the light sensing area 242CB is adjacent to another of the source/drain electrodes 252S and 252D.

Through the configuration, during the operation of the light sensing device 120, by applying an appropriate voltage onto the gate electrode 222, the switch area 242CA and the light sensing area 242CB of the semiconductor layer 242 sense light and thus generate electrical current, and the electrical current is detected to calculate the light intensity. In an example, a positive voltage is applied onto the gate electrode 222 and thus turning on the switch area 242CA, and the semiconductor layer 242 senses light and thus generates electrical current; at this point, the magnitude of the electrical current is mainly controlled by the light sensing area 242CB. In another example, a negative voltage is applied onto the gate electrode 222 and thus inhibiting the switch area 242CA, and the semiconductor layer 242 senses light and thus generates electrical current; at this point, the magnitude of the electrical current is mainly controlled by the switch area 242CA and the light sensing area 242CB. In the example where the gate electrode 222 is applied with the negative voltage, a change of the current induced by the light intensity in the is more obvious, and therefore the light sensing device 120 has a higher light-intensity resolution. In the present embodiments, the light sensing device 120, having an advantage of high light-intensity resolution, and can be used in optical fingerprint recognition. By sensing light reflected by fingerprint, fingerprint recognition can be achieved with improved accuracy.

Herein, “inhibiting” the switch area 342CA is referred to as increasing a value of electric resistance of the semiconductor layer 242 by controlling an external electric field (e.g., the electric field generated by voltages applied onto the gate electrode 222). On the other hand, “turning on” the switch area 242CA is referred to as decreasing the value of electric resistance of the semiconductor layer 242 by controlling the external electric field (i.e., the electric field generated by voltages applied onto the gate electrode 222).

Similarly, for the reference light sensing device 130, the semiconductor layer 244 has a channel region 244C between the source/drain electrodes 254S and 254D, and the gate electrode 224 is offset disposed such that the channel region 244C is divided into a switch area 244CA and a light sensing area 244CB. In the present embodiments, with the design of the offset gate electrode, the switch area 244CA is adjacent to one of the source/drain electrodes 254S and 254D, and the light sensing area 244CB is adjacent to another of the source/drain electrodes 254S and 254D. Other details of the reference light sensing device 130 is similar to the configuration of the light sensing device 120, and thus not repeated herein.

In order to simulate the dark current in the light sensing device 120, structural configurations of the reference light sensing device 130 may be the same as those of the light sensing device 120. For example, the length, width, material, and other characteristics/features of the channel region 244C of the reference light sensing device 130 can be substantially the same as those of the channel region 242C of the light sensing device 120. In some examples, lengths of the switch area 244CA and the light sensing area 244CB may be substantially the same as lengths of the switch area 242CA and the light sensing area 242CB, respectively. Furthermore, the length, width, material, and other characteristics/features of other elements of the reference light sensing device 130 (e.g., the gate electrode 224) can be substantially the same as those of other elements of the light sensing device 120 (e.g., the gate electrode 222). While the structures of the light sensing device 120 and the reference light sensing device 130 are substantially the same, the sensing switch device 140 may have a different structure from the structures of the devices 120 and 130. For example, the length, width, thickness, material, or other characteristics/features of elements of the sensing switch device 140 (e.g., the gate electrode 226 or the channel region 246C) may be different from that of corresponding elements of the light sensing device 120 (e.g., the gate electrode 222 or the channel region 242C). In some embodiments, for the same element (e.g., layers and structures), a difference between element characteristics/features of the light sensing device 120 and the reference light sensing device 130 is much less than a difference between element characteristics/features of the light sensing device 120 and the sensing switch device 140. For example, a first difference is between a length of the channel region 242C of the light sensing device 120 and a length of the channel region 244C of the reference light sensing device 130, a second difference is between the length of the channel region 242C of the light sensing device 120 and a length of the channel region 246C of the sensing switch device 140, and the second difference is greater than the first difference.

Reference is made to FIG. 2B. An insulating layer 260 and a suitable structure 270 may overlay the light sensing device 120 and the reference light sensing device 130. The insulating layer 260 may be formed by depositing a suitable insulating material, such as silicon nitride, silicon oxide, silicon oxynitride, or a combination thereof.

The structure 270 may include a light transmitting region 272 and a light non-transmitting region 274. The light transmitting region 272 is substantially transparent, and the light transmitting region 272 is located directly above the channel region 242C of the semiconductor layer 242 of the light sensing device 120, so that the light sensing device 120 can receive light. The light non-transmitting region 274 is opaque, and the light non-transmitting region 274 is located directly above the channel region 244C of the semiconductor layer 244 of the reference light sensing device 130, thereby blocking light from entering the reference light sensing device 130. In some embodiments, the light non-transmitting region 274 of the structure 270 may include a light shielding layer 280 to achieve opaque optical properties. The light shielding layer 280 may have a light transmittance of less than 20%, and therefore is capable of shielding light. For example, the light shielding layer 280 may be formed of a metal material, a black matrix, or other opaque materials.

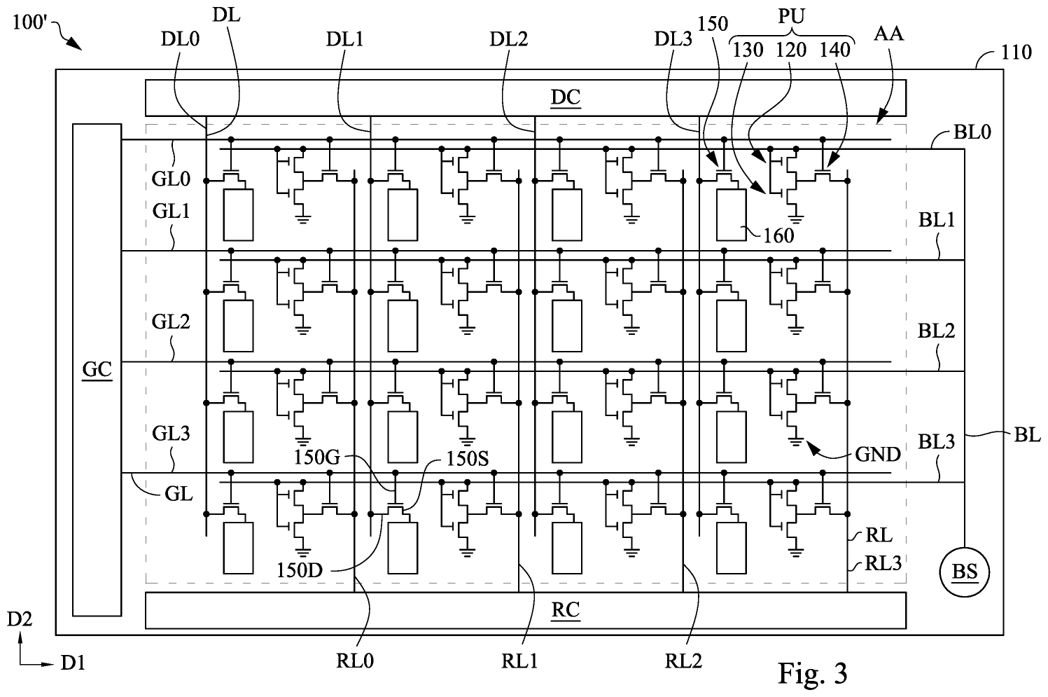

FIG. 3 is a schematic circuit diagram of a light sensing display panel 100′ according to some embodiments. In the present embodiments, the light sensing display panel 100′ is similar to the light sensing panel 100 of FIG. 1A, except that the pixel unit PU may further include a display switch device 150 and a pixel electrode 160 in the present embodiments, so that the light sensing display panel 100′ can achieve the display effect.

The display switch device 150 may include a control terminal 150G, a first terminal 150D, and a second terminal 150S, in which the control terminal 150G is configured to control whether to establish an electrical conduction between the first terminal 150D and the second terminal 150S or not. The control terminal 150G can be connected to the scan line GL. The light sensing display panel 100′ may further include a data line DL, and the first terminal 150D and the second terminal 150S are respectively connected to the data line DL and the pixel electrode 160. The light sensing display panel 100′ further includes a data driving circuit DC to time-sequentially provide suitable data signals to respective data lines DL (e.g., the data lines DLO-DL3). In some embodiments, the data driving circuit DC may be directly disposed on the substrate. Alternatively, in some other embodiments, the data driving circuit DC can be disposed on a flexible circuit board, and the flexible circuit board is connected to the peripheral area PA of the substrate 110. Through the configuration, through the control of the data driving circuit DC and the scan lines GL, the data signals provided by the data driving circuit DC can be time-sequentially sent to the respective pixel electrodes 160 through the data lines DL, thereby controlling the light intensity of respective pixels and achieving display purpose.

In some embodiments, the light sensing display panel 100′ may be a liquid crystal display panel (LCD), and the pixel electrodes 160 may be configured to modulate the liquid crystal layer. Alternatively, in some embodiments, the light sensing display panel 100′ may be an organic light-emitting diode (e.g., active-matrix organic light-emitting diode (AMOLED)) panel or a light-emitting diode (LED) panel, The pixel electrode 160 can be used to control the organic light-emitting layer or the light-emitting diode.

In the present embodiments, as the display switch device 150 and the sensing switch device 140 of the same pixel unit PU are controlled by the same scan line GL, the display switch device 150 and the sensing switch device 140 in the same pixel unit PU can be turned on at the same time point. Through the configuration, in the pixel unit PU, at the same time point, an electrical conduction is built between the data line DL and the pixel electrode 160 through the display switch device 150 to achieve the display effect, and an electrical conduction is built between the light sensing device 120 and the readout line RL through the sensing switch device 140 to achieve the purpose of sensing light. By arranging the light sensing device 120 and the pixel electrode 160 in the same pixel unit PU, the resolution of the light sensing device 120 is comparable to the resolution of the pixel electrode 160 for display, thereby improving the sensing resolution. Other details of the present embodiment are similar to those described above, and not repeated herein.

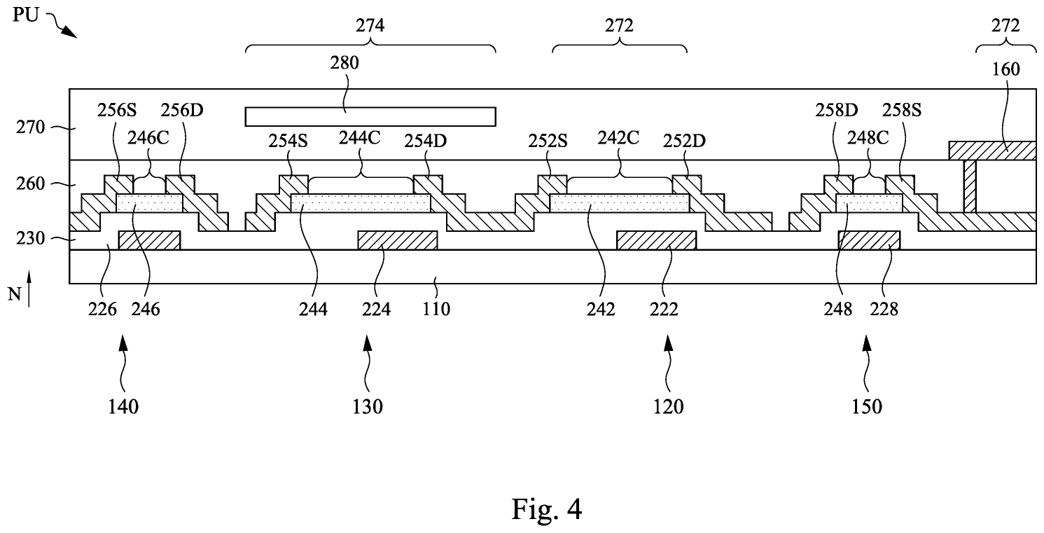

FIG. 4 is a schematic cross-sectional view of portions of a light sensing display panel 100′ according to some embodiments of the present invention. In some embodiments, the aforementioned light sensing device 120, the reference light sensing device 130, the sensing switch device 140, and the display switch device 150 may be thin film transistors formed by the same fabrication process, and their layers have substantially the same material and thickness.

For example, the display switch device 150 may include a gate electrode 228, a semiconductor layer 248, and source/drain electrodes 258D and 258S, in which the gate electrode 228 and the source/drain electrodes 258D and 258S respectively correspond to a control terminal 150G, a first terminal 150D and a second terminal 150S FIG. 3. The gate electrodes 222-228 may be formed by patterning the same conductive layer, so that the gate electrodes 222-228 may include the same material and have substantially the same thickness. The semiconductor layers 242-248 may be formed by patterning the same semiconductor thin film, so that the semiconductor layers 242-248 may include the same material and have substantially the same thickness. The source/drain electrodes 252S and 252D, 254S and 254D, 256S and 256D, and 258S and 258D may be formed by patterning the same conductive layer, so that the source/drain electrodes 252S and 252D, 254S and 254D, 256S and 256D, and 258S and 258D may include the same material and have substantially the same thickness. In the present embodiments, a suitable conductive material, such as a transparent conductive material (e. g., indium tin oxide) or an opaque conductive material, can be deposited on the insulating layer 260 and subjected to a patterning process to form the pixel electrode 160. Afterwards, the structure 270 is formed on the pixel electrode 160. In some embodiments, the light transmitting region 272 of the structure 270 is located directly above the pixel electrode 160 so as to achieve the display effect.

In the present embodiments, while the light sensing device 120 and the reference light sensing device 130 have the same structure, the display switch device 150 may have a structure different from that of the devices 120 and 130. For example, the length, width, thickness, material, or other characteristics/features of respective elements of the display switch device 150 (e.g., the gate electrode 228 or the channel region 248C) may be different from that of the corresponding elements of the light sensing device 120 (e. g., the gate electrode 222 or the channel region 242C). In some embodiments, for the same element (e.g., layers and structures), a difference between element characteristics/features of the light sensing device 120 and the reference light sensing device 130 is much less than a difference between element characteristics/features of the light sensing device 120 and the display switch device 150. For example, a first difference is between a length of the channel region 242C of the light sensing device 120 and a length of the channel region 244C of the reference light sensing device 130, a second difference is between the length of the channel region 242C of the light sensing device 120 and a length of the channel region 248C of the display switch device 150, and the second difference is greater than the first difference. Other details of the present embodiment are similar to those described above, and not repeated herein.

In some embodiments of the present invention, the light sensing device is used to receive light to generate current, and a reference light sensing device that is not exposed to the light is designed to be connected in series with the light sensing device, thereby directly deducting a dark current from the current of the light sensing device. This design can improve the contrast of the read current, thereby improving the contrast of the image.

The foregoing outlines features of several embodiments so that those skilled in the art may better understand the aspects of the present disclosure. Those skilled in the art should appreciate that they may readily use the present invention as a basis for designing or modifying other processes and structures. Those skilled in the art should also realize that such equivalent constructions do not depart from the spirit and scope of the present invention, and that they may make various changes, substitutions, and alterations herein without departing from the spirit and scope of the present invention.

What is claimed is:

1. A light sensing panel, comprising:
a substrate having an array region and a peripheral region at at least one side of the array region;
at least one readout line extending at least over the array region of the substrate;
at least one scan line extending at least over the array region of the substrate; and
at least one pixel unit over the array region of the substrate and electrically connected to the readout line and the scan line, wherein the pixel unit at least comprises:
a sensing switch device comprising a control terminal, a first terminal, and a second terminal, wherein the first terminal of the sensing switch device is connected to the readout line;
a light sensing device connected between the second terminal of the sensing switch device and a voltage source; and
a reference light sensing device connected between the second terminal of the sensing switch device and a grounded source.

2. The light sensing panel of claim 1, wherein a control terminal of the light sensing device and a control terminal of the reference light sensing device are electrically connected to the voltage source.

3. The light sensing panel of claim 1, wherein the light sensing device, the reference light sensing device, and the sensing switch device are thin-film transistors.

4. The light sensing panel of claim 1, wherein a length of a channel region of the light sensing device is the same as a length of a channel region of the reference light sensing device.

5. The light sensing panel of claim 1, wherein a first difference is between a length of a channel region of the light sensing device and a length of a channel region of the reference light sensing device, a second difference is between the length of the channel region of the light sensing device and a length of a channel region of the sensing switch device, and the second difference is greater than the first difference.

6. The light sensing panel of claim 1, wherein the light sensing device comprises a gate electrode, two source/drain electrodes, and a channel region between the source/drain electrodes, the channel region comprises a first portion and a second portion, the first portion of the channel region overlaps the gate electrode, and the second portion of the channel region does not overlap the gate electrode.

7. The light sensing panel of claim 6, wherein the reference light sensing device comprises a reference gate electrode, two reference source/drain electrodes, and a reference channel region between the reference source/drain electrodes, the reference channel region comprises a first reference portion and a second reference portion, the first reference portion of the reference channel region overlaps the reference gate electrode, and the second reference portion of the reference channel region does not overlap the reference gate electrode.

8. The light sensing panel of claim 7, wherein a length of the first reference portion of the reference channel region of the reference light sensing device is the same as a length of the first portion of the channel region of the light sensing device.

9. The light sensing panel of claim 6, wherein the first portion of the channel region is adjacent to one of the source/drain electrodes, and the second portion of the channel region is adjacent to another one of the source/drain electrodes.

10. A light sensing display panel, comprising:
the light sensing panel of claim 1; and
at least one data line disposed over the substrate, wherein the pixel unit further comprises a display switch device and a pixel electrode, a control terminal of the display switch device is connected to the scan line, and two terminals of the display switch device are respectively electrically connected to the data line and the pixel electrode.
